(19) United States
(12) Patent Application Publication
(10) Pub. No.: US 2026/0240004 A1
(43) Pub. Date: Aug. 13, 2026

(54) SEMICONDUCTOR STRUCURE WITH REDUCED KEEP-OUT-ZONE BETWEEN THROUGH-SUBSTRATE VIA AND DEVICE REGION AND METHODS OF MAKING THE SAME

(71) Applicant: Taiwan Semiconductor Manufacturing Company Limited, Hsinchu (TW)

(72) Inventors: Chang-Yu HUANG, Hsinchu (TW); Chih-Pin HUNG, Hsinchu (TW); Hung-Han LIN, Hsinchu (TW); Wan-Lin TSAI, Hsinchu (TW)

(21) Appl. No.: 19/051,409

(22) Filed: Feb. 12, 2025

(51) Int. Cl. H01L 23/538; H01L 21/762; H01L 23/498

(52) U.S. Cl. CPC H10W 70/611; H10W 10/0143; H10W 10/17; H10W 70/635; H10W 70/65; H10W 70/658

(57) ABSTRACT

A semiconductor device structure includes a first region including semiconductor devices, and a second region including a through-substrate via (TSV) and a deep trench isolation (DTI) structure located between the TSV and the first region. The DTI may have a vertical depth of at least 3 μm, such as between about 5 μm and about 10 μm, which may help shield the semiconductor devices in the first region from stress caused by the TSV. Accordingly, the TSV may not negatively affect performance of nearby semiconductor devices, and the TSV and the semiconductor devices may be located closer to one another (e.g., <3 μm), which may help to maximize the number of devices on the structure and improve cost efficiency. In some embodiments, the ratio of the depth of the DTI structure to the distance between the TSV and the nearest semiconductor device may be greater than 1.

### BACKGROUND

The semiconductor industry has continually grown due to continuous improvements in integration density of various electronic components, e.g., transistors, diodes, resistors, capacitors, etc. These improvements in integration density have come, in part, from successive reductions in minimum feature size, which allows more components to be integrated into a given area.

Additional improvements in integration density may be achieved through packaging of multiple semiconductor structures, including by placing chips over chips to provide three-dimensional devices. These three-dimensional devices may provide improved integration density and other advantages because of the decreased length of interconnects between the stacked chips. However, there are many challenges related to three-dimensional devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first structure according to an embodiment of the present disclosure.

FIG. 2A is a top view of a semiconductor device structure according to various embodiments of the present disclosure.

FIG. 2B is a vertical cross-section view of the semiconductor device structure taken along line A-A′ in FIG. 2A.

FIG. 2C is a vertical cross-section view of the semiconductor device structure taken along line B-B′ in FIG. 2A.

FIG. 3A is a top view of a semiconductor device structure including a through-substrate via (TSV) formed within a TSV region of the semiconductor device structure according to various embodiments of the present disclosure.

FIG. 3B is a vertical cross-section view of the semiconductor device structure taken along line A-A′ in FIG. 3A.

FIG. 3C is a vertical cross-section view of the semiconductor device structure taken along line B-B′ in FIG. 3A.

FIG. 4A is a side cross-section view of a semiconductor device structure according to another embodiment of the present disclosure.

FIG. 4B is a side cross section view of a semiconductor device structure including a TSV formed within a TSV region of the semiconductor device structure according to an embodiment of the present disclosure.

FIG. 5A is a vertical cross-section view of a semiconductor device structure according to another embodiment of the present disclosure.

FIG. 5B is a vertical cross-section view of the semiconductor device structure of FIG. 5A viewed along a transverse direction according to an embodiment of the present disclosure.

FIG. 6A is a vertical cross-section view of a semiconductor device structure according to another embodiment of the present disclosure.

FIG. 6B is a vertical cross-section view of a semiconductor device structure according to another embodiment of the present disclosure.

FIG. 6C is a vertical cross-section view of a semiconductor device structure according to another embodiment of the present disclosure.

FIG. 7A is a vertical cross-section view of a semiconductor device structure including a plurality of deep trench isolation (DTI) structures arranged along a line according to various embodiments of the present disclosure.

FIG. 7B is a vertical cross-section view of the semiconductor device structure of FIG. 7A including a TSV formed through several of the DTI structures and surrounded on opposite sides by the remaining DTI structures according to various embodiments of the present disclosure.

FIG. 8A is a vertical cross-section view a semiconductor device structure including three DTI structures that are spaced apart from one another arranged along a line according to various embodiments of the present disclosure.

FIG. 8B is a vertical cross-section view of the semiconductor device structure of FIG. 8A including a TSV formed through the middle DTI structure and surrounded on opposite sides by the remaining two DTI structures according to various embodiments of the present disclosure.

FIG. 9A is a vertical cross-section view of a semiconductor device structure including a DTI structure according to various embodiments of the present disclosure.

FIG. 9B is a vertical cross-section view of the semiconductor device structure of FIG. 9A including a TSV formed through the DTI structure according to various embodiments of the present disclosure.

FIG. 10 is a vertical cross-section view of a semiconductor device structure according to another embodiment of the present disclosure.

FIG. 11A is horizontal cross-section view of a semiconductor device structure illustrating a device region and a TSV region including a TSV and a circular shaped DTI structure surrounding the TSV according to an embodiment of the present disclosure.

FIG. 11B is horizontal cross-section view of a semiconductor device structure illustrating a device region and a TSV region including a TSV and a square shaped DTI structure surrounding the TSV according to another embodiment of the present disclosure.

FIG. 11C is horizontal cross-section view of a semiconductor device structure illustrating a device region and a TSV region including a TSV and a rectangular shaped DTI structure surrounding the TSV according to another embodiment of the present disclosure

FIG. 11D is horizontal cross-section view of a semiconductor device structure illustrating a device region and a TSV region including a TSV and a hexagonal shaped DTI structure surrounding the TSV according to another embodiment of the present disclosure.

FIG. 11E is horizontal cross-section view of a semiconductor device structure illustrating a device region and a TSV region including a TSV and an octagonal shaped DTI structure surrounding the TSV according to another embodiment of the present disclosure.

FIG. 11F is horizontal cross-section view of a semiconductor device structure illustrating a device region and a TSV region including a TSV and a polygonal shaped DTI structure surrounding the TSV according to another embodiment of the present disclosure

FIG. 12 is a flow diagram illustrating steps of a method of forming a semiconductor device structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

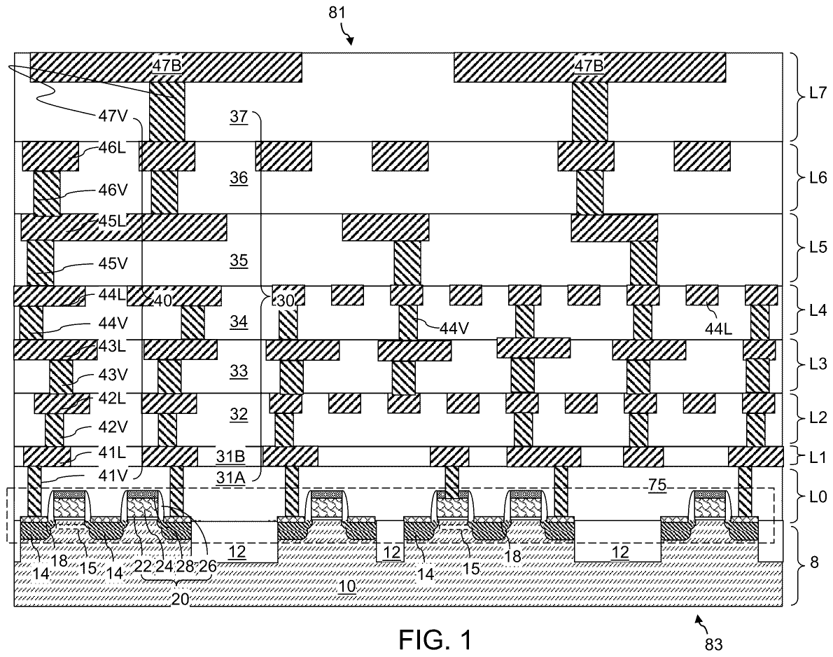

Referring to FIG. 1, a vertical cross-sectional view of a first structure according to an embodiment of the present disclosure is illustrated. The first structure includes a substrate 8 that contains a semiconductor material layer 10. The substrate 8 may include a bulk semiconductor substrate such as a silicon substrate in which the semiconductor material layer continuously extends from a top surface of the substrate 8 to a bottom surface of the substrate 8, or a semiconductor-on-insulator layer including the semiconductor material layer 10 as a top semiconductor layer overlying a buried insulator layer (such as a silicon oxide layer).

Semiconductor devices such as field effect transistors (FETs) may be formed on, and/or in, the semiconductor material layer 10 during a front-end-of-line (FEOL) operation. For example, shallow trench isolation structures 12 may be formed in an upper portion of the semiconductor material layer 10 by forming shallow trenches and subsequently filling the shallow trenches with a dielectric material such as silicon oxide. Other suitable dielectric materials are within the contemplated scope of disclosure. Various doped wells (not expressly shown) may be formed in various regions of the upper portion of the semiconductor material layer 10 by performing masked ion implantation processes.

Gate structures 20 may be formed over the top surface of the substrate 8 by depositing and patterning a gate dielectric layer, a gate electrode layer, and a gate cap dielectric layer. Each gate structure 20 may include a vertical stack of a gate dielectric 22, a gate electrode 24, and a gate cap dielectric 28, which is herein referred to as a gate stack (22, 24, 28). Ion implantation processes may be performed to form extension implant regions, which may include source extension regions and drain extension regions. Dielectric gate spacers 26 may be formed around the gate stacks (22, 24, 28). Each assembly of a gate stack (22, 24, 28) and a dielectric gate spacer 26 constitutes a gate structure 20. Additional ion implantation processes may be performed that use the gate structures 20 as self-aligned implantation masks to form deep active regions. Such deep active regions may include deep source regions and deep drain regions. Upper portions of the deep active regions may overlap with portions of the extension implantation regions. Each combination of an extension implantation region and a deep active region may constitute an active region 14, which may be a source region or a drain region depending on electrical biasing. A semiconductor channel 15 may be formed underneath each gate stack (22, 24, 28) between a neighboring pair of active regions 14. Metal-semiconductor alloy regions 18 may be formed on the top surface of each active region 14. Field effect transistors may be formed on the semiconductor material layer 10. Each field effect transistor may include a gate structure 20, a semiconductor channel 15, a pair of active regions 14 (one of which functions as a source region and another of which functions as a drain region), and optional metal-semiconductor alloy regions 18. Complementary metal-oxide-semiconductor (CMOS) circuits 75 may be provided on the semiconductor material layer 10.

Various interconnect-level structures (e.g., L0 through L7) may be subsequently formed. In various embodiments, the interconnect-level structures may be formed during a back-end-of-line (BEOL) operation. In various embodiments described in further detail below, one or more through-substrate vias (TSVs) (not illustrated in FIG. 1) may additionally be formed during a BEOL operation. Lower interconnect-level structures may include, for example, a contact-level structure L0, a first interconnect-level structure L1, a second interconnect-level structure L2, and a third interconnect-level structure L3. The contact-level structure L0 may include a planarization dielectric layer 31A including a planarizable dielectric material such as silicon oxide and various contact via structures 41V contacting a respective one of the active regions 14 or the gate electrodes 24 and formed within the planarization dielectric layer 31A. The first interconnect-level structure L1 includes a first interconnect level dielectric (ILD) layer 31B and first metal lines 41L formed within the first ILD layer 31B. The first ILD layer 31B is also referred to as a first line-level dielectric layer. The first metal lines 41L may contact a respective one of the contact via structures 41V. The second interconnect-level structure L2 includes a second ILD layer 32, which may include a stack of a first via-level dielectric material layer and a second line-level dielectric material layer or a line-and-via-level dielectric material layer. The second ILD layer 32 may have formed there within second interconnect-level metal interconnect structures (42V, 42L), which includes first metal via structures 42V and second metal lines 42L. Top surfaces of the second metal lines 42L may be coplanar with the top surface of the second ILD layer 32. The third interconnect-level structure L3 includes a third ILD layer 33, which may include a stack of a first via-level dielectric material layer and a second line-level dielectric material layer or a line-and-via-level dielectric material layer. The third ILD layer 33 may have formed there within third interconnect-level metal interconnect structures (43V, 43L) may be formed in the third ILD layer 33, which may include second metal via structures 43V and third metal lines 43L.

Additional interconnect-level structures may be subsequently formed, which are herein referred to as upper interconnect-level structures (L4, L5, L6, L7). For example, the upper interconnect-level structures (L4, L5, L6, L7) may include a fourth interconnect-level structure L4, a fifth interconnect-level structure L5, a sixth interconnect-level structure L6, and a seventh interconnect-level structure L7. The fourth interconnect-level structure L4 may include a fourth ILD layer 34 having formed therein fourth interconnect-level metal interconnect structures (44V, 44L), which may include third metal via structures 44V and fourth metal lines 44L. The fifth interconnect-level structure L5 may include a fifth ILD layer 35 having formed therein fifth interconnect-level metal interconnect structures (45V, 45L), which may include fourth metal via structures 45V and fifth metal lines 45L. The sixth interconnect-level structure L6 may include a sixth ILD layer 36 having formed therein sixth interconnect-level metal interconnect structures (46V, 46L), which may include fifth metal via structures 46V and sixth metal lines 46L. The seventh interconnect-level structure L7 may include a seventh ILD layer 37 having formed therein sixth metal via structures 47V (which are seventh interconnect-level metal interconnect structures) and metal bonding pads 47B. The metal bonding pads 47B may be configured for solder bonding (which may employ C4 ball bonding or wire bonding), or may be configured for metal-to-metal bonding (such as copper-to-copper bonding).

Each ILD layer may be referred to as an ILD layer 30. Each of the interconnect-level metal interconnect structures may be referred to as a metal interconnect structure 40. Each contiguous combination of a metal via structure and an overlying metal line located within a same interconnect-level structure (L2-L7) may be formed sequentially as two distinct structures by employing two single damascene processes, or may be simultaneously formed as a unitary structure employing a dual damascene process. Each of the metal interconnect structure 40 may include a respective metallic liner (such as a layer of TiN, TaN, or WN having a thickness in a range from 2 nanometers (nm) to 20 nm) and a respective metallic fill material (such as W, Cu, Co, Mo, Ru, other elemental metals, or an alloy or a combination thereof). Other suitable materials for use as a metallic liner and metallic fill material are within the contemplated scope of disclosure. Various etch stop dielectric layers and dielectric capping layers may be inserted between vertically neighboring pairs of ILD layers 30, or may be incorporated into one or more of the ILD layers 30.

In some embodiments, one or more additional devices, such as memory devices, transistor devices (e.g., thin-film transistor (TFT) devices), capacitors, and the like, may be formed within in one or more of the interconnect level structures (e.g., L1-L7) using a BEOL operation. The additional devices may be electrically coupled to the semiconductor devices (e.g., FETs) that may be formed on, and/or in, the semiconductor material layer 10 via the metal interconnect structures 40. Further, while the present disclosure is described using an embodiment in which a set of eight interconnect-level structures are formed, embodiments are expressly contemplated herein in which a different number of interconnect-level structures is used.

In a structure as shown in FIG. 1, the electrical interconnections to the various devices of the structure may be made through the front side 81 of the structure (e.g., through the metal bonding pads 47B and the metal interconnect structures 40 of the various interconnect level structures L0-L7). It may also be desirable to provide electrical interconnections through the back side 83 of the structure (i.e., through the side of the substrate 8 opposite the interconnect level structures L0-L7). In various embodiments, a structure as shown in FIG. 1 may include one or more through-substrate vias (TSVs) that may be formed through the substrate 8. In embodiments in which the substrate 8 includes a silicon substrate, the through-substrate vias may also be referred to as “through-silicon vias.” The one or more TSVs may be electrically coupled to the metal interconnect structures 40 of the interconnect level structures L0-L7 to enable interconnections to the various devices of the structure through the back side 83 of the structure.

In various embodiments, TSVs may help to enable advanced 3D integrated circuits (3D ICs) and other packaging technologies. Advantages provided by TSVs may include, for example, improved integration density by facilitating the vertical stacking of multiple semiconductor dies, which may provide increased device density without increasing footprint. In addition, TSVs may provide for shortened interconnect lengths between stacked dies, which may help to improve performance by reducing signal propagation delay, lowering power consumption, and improving signal integrity. TSVs may also facilitate the integration of different technologies (e.g., logic, memory, sensors, RF) into a single package, enabling versatile and high-performance system-on-chip (SoC) devices. TSVs may be particularly useful for technologies such as high-bandwidth memory (HBM) and high-performance computing (HPC) applications.

However, forming TSVs in the semiconductor device structure may add complexity and cost to the manufacturing process, and may also increase thermal stress within the substrate 8. In addition, TSVs may take up valuable real estate on the die that could otherwise be used for fabrication of semiconductor devices, such as the CMOS circuitry 75 shown in FIG. 1. Accordingly, device designers may prefer locating the TSVs as close as possible to the semiconductor devices to maximize the total area of the die containing semiconductor devices.

However, there may be a tradeoff between minimizing the space between TSVs and the adjacent semiconductor devices and maintaining a high performance of the semiconductor devices. As noted above, TSVs may impart thermal stresses on the substrate 8, which may result in changes to the electrical characteristics of the semiconductor devices formed on and/or within the substrate 8. These effects are more pronounced the closer the semiconductor devices are to the TSVs. For example, locating field effect transistors close to the TSVs may cause their threshold voltages to shift, which can negatively affect device performance. Accordingly, device designers frequently define a “keep out zone” (KOZ) of 3 μm or more surrounding each of the TSVs within which the location of device structures may be avoided.

Various embodiments of the present disclosure include semiconductor device structures that include a first region (i.e., a device region) that includes semiconductor devices, such as above-described field-effect transistors (FETs), and a second region (i.e., a TSV region) that includes a TSV and one or more deep trench isolation (DTI) structures. The one or more DTI structures may be located within the “keep out zone” (KOZ) surrounding the TSV, and at least a portion of a DTI structure may be located between the TSV and the first (i.e., device) region of the semiconductor device structure.

In various embodiments, each DTI structure may include a dielectric material extending into the substrate to a vertical depth of at least 3 μm, such as between about 5 μm and about 10 μm. By extending relatively deeply into the substrate, the DTI structure(s) may provide improved resistance to the stress generated by the TSV. In various embodiments, the DTI structure(s) may effectively block the stress caused by TSV from significantly impacting the device region of the semiconductor device structure. Accordingly, the performance of semiconductor devices closest to the TSV may not be negatively affected by the presence of the nearby TSV.

In various embodiments, providing one or more DTI structures between the TSV and the device region may enable the minimization of the KOZ, such that semiconductor devices may be fabricated closer to the TSV(s) without the TSV(s) negatively impacting the device performance. Consequently the total area of the semiconductor device structure that is usable for fabrication of semiconductor devices may be increased. In some embodiments, the minimum distance between the TSV and the semiconductor devices of the device region may be less than 3 μm, such as ≤0.5 μm. In some embodiments, the ratio of the depth of the DTI structure(s) to the minimum distance between the TSV and the semiconductor devices of the device region may be greater than 1, such as ≥6:1, including ≥10:1.

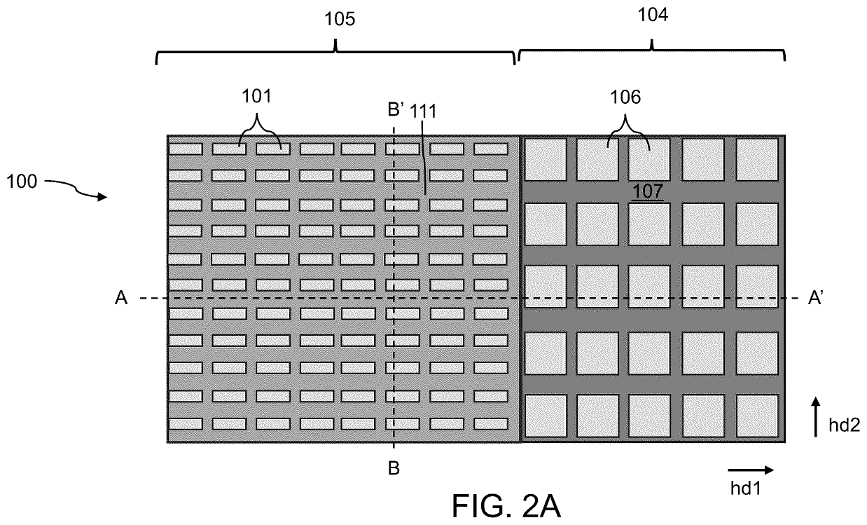

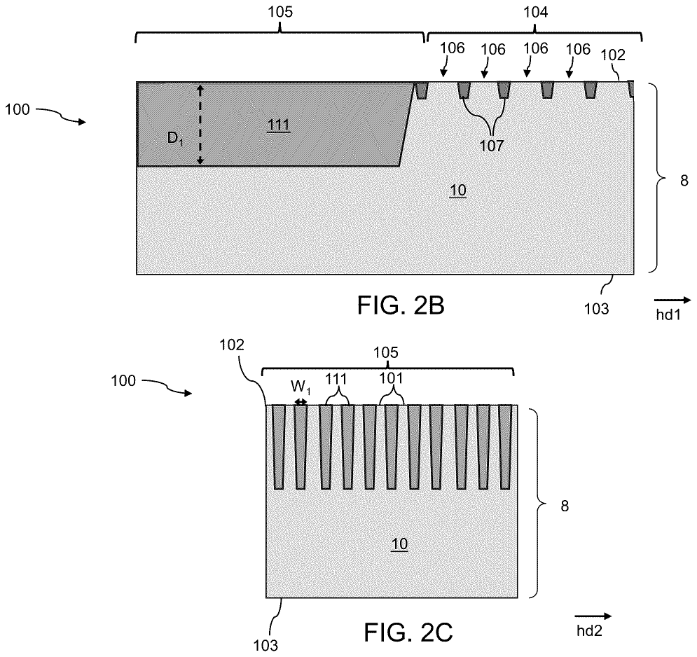

FIG. 2A is a top view of a semiconductor device structure 100 according to various embodiments of the present disclosure. FIG. 2B is a vertical cross-section view of the semiconductor device structure 100 taken along line A-A′ in FIG. 2A. FIG. 2C is a vertical cross-section view of the semiconductor device structure 100 taken along line B-B′ in FIG. 2A. Referring to FIGS. 2A-2C, the semiconductor device structure 100 may include a device region 104 and a TSV region 105. The device region 104 may include a plurality of oxide definition (OD) areas 106. Each OD area 106, which may sometimes also be referred to as an “oxide diffusion” area, may include an area of the upper portion of the semiconductor material layer 10 of the substrate 8 in which semiconductor devices (e.g., field effect transistors) may be formed. In particular, ion implantation processes may be performed and gate structures 20 may be formed as described above to form transistors including source and drain regions and channel regions within each of the OD areas 106. The OD areas 106 may be formed to be located between inactive active areas 107 in which semiconductor devices may not be formed. In the embodiment of FIGS. 2A-2C, the inactive areas 107 may include shallow trench isolation (STI) structures 107, which in some embodiments may be formed in a grid pattern surrounding each of the OD areas 106. The STI structures 107 may include a dielectric material such as silicon oxide, although other suitable dielectric materials are within the contemplated scope of disclosure. In other embodiments, the inactive areas 107 between the OD areas 106 may include other isolation features, such as field oxide (FOX) areas.

Referring again to FIGS. 2A-2C, the semiconductor device structure 100 may further include a TSV region 105 within which one or more TSVs may be subsequently formed. In various embodiments, the TSV region 105 may not include functional semiconductor devices (e.g., field effect transistors). In some embodiments, the TSV region 105 may include a plurality of “dummy” OD areas 101. The dummy OD areas 101 of the TSV region 105 may be similar or identical to the OD areas 106 in the device region 104. Each dummy OD area 101 may include an area of the upper portion of the semiconductor material layer 10 of the substrate 8. The OD areas 101 may be separated from one another by isolation features. In various embodiments, the isolation features may include at least one deep trench isolation (DTI) structure 111. The DTI structures 111 may include a suitable dielectric material such as silicon oxide, silicon nitride, silicon oxynitride, etc., including various combinations thereof. Other suitable dielectric materials for the DTI structures 111 are within the contemplated scope of disclosure. In various embodiments, the DTI structure(s) 111 may be formed by performing an etching process through a photolithographically-patterned mask to form one or more trenches in the semiconductor material layer 10 of the substrate 8. Following the etching process, the patterned mask may be removed using a suitable process, such as by ashing or dissolution using a solvent. Dielectric material may then be deposited over the front side 102 of the substrate 8 and within each of the trenches using a suitable deposition process, such as chemical vapor deposition (CVD), physical vapor deposition (PVD), atomic layer deposition (ALD), high density plasma CVD (HDPCVD), metalorganic CVD (MOCVD), plasma enhanced CVD (PECVD), sputtering, laser ablation, or the like. Other suitable deposition processes are within the contemplated scope of disclosure. A planarization process, such as a chemical mechanical planarization (CMP) process, may then be performed to remove excess dielectric material from over the front side 102 of the substrate 8 to provide one or more discrete DTI structures 111 within the substrate 8.

In the embodiment of FIGS. 2A-2C, the TSV region 105 includes a plurality of DTI structures 111 formed in a grid pattern surrounding each of the dummy OD areas 101. However, other configurations of DTI structures 111 may be utilized, such as described in further detail below. Referring to FIG. 2B, each DTI structure 111 may have a vertical depth dimension D₁. In various embodiments, the vertical depth dimension D₁ of each DTI structure 111 may be greater than 3 μm. In some embodiments, the vertical depth dimension D₁ of each DTI structure 111 may be greater than about 5 μm, such as between about 5 μm and about 10 μm. Referring to FIG. 2C, the upper surface of each DTI structure 111 may have a width dimension W₁. In various embodiments, the width dimension W₁ of each DTI structure 111 may be at least about 0.5 μm along both the first horizontal direction hd1 and the second horizontal direction hd2.

In the embodiment shown in FIGS. 2A-2C, the OD areas 106 in the device region 104 have different sizes and shapes than the dummy OD areas 101 in the TSV region 105. However, in other embodiments, the OD areas 106 and the dummy OD areas 101 may have the same sizes and/or shapes. Further, although FIGS. 2A-2C illustrate a single device region 104 and a single TSV region 105, it will be understood that the semiconductor device structure 101 may include more than one device region 104 and/or more than one TSV region 105.

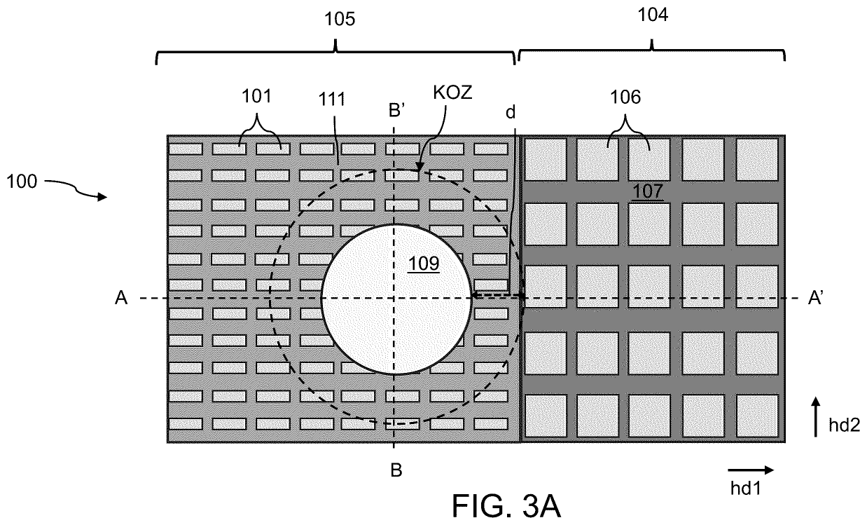

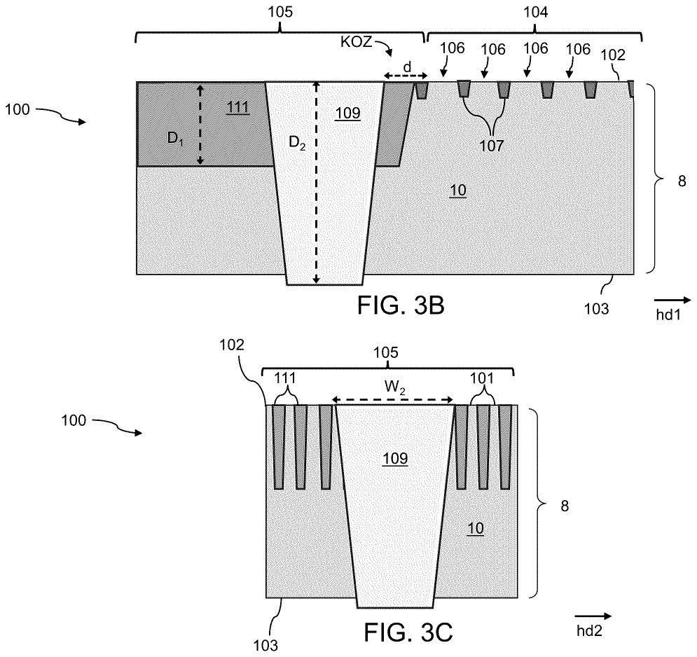

FIG. 3A is a top view of a semiconductor device structure 100 including a TSV 109 formed within a TSV region 105 of the semiconductor device structure 100 according to various embodiments of the present disclosure. FIG. 3B is a vertical cross-section view of the semiconductor device structure 100 taken along line A-A′ in FIG. 3A. FIG. 3C is a vertical cross-section view of the semiconductor device structure 100 taken along line B-B′ in FIG. 3A. Referring to FIGS. 3A-3C, a TSV 109 may be formed in the TSV region 104 of the semiconductor device structure 100. The TSV 109 may extend within the substrate 8 of the semiconductor device structure 100 and may provide an electrical pathway between the front side 102 and the back side 104 of the substrate 8. The TSV 109 may include a suitable electrically conductive material, such as one or more metallic materials. In some embodiments, the TSV 109 may include a metallic liner (such as a layer of TiN, TaN, WN, etc.) and a metallic fill material (such as Cu, W, Co, Mo, Ru, other elemental metals, or an alloy or a combination thereof). Other suitable materials for the TSV 109 are within the contemplated scope of disclosure.

In various embodiments, the TSV 109 may be formed by performing an etching process through a photolithographically-patterned mask to form a TSV opening in the substrate 8. Following the etching process, the patterned mask may be removed using a suitable process, such as by ashing or dissolution using a solvent. Conductive material may be deposited within the TSV opening using a suitable deposition process, such as physical vapor deposition (PVD), sputtering, chemical vapor deposition (CVD), atomic layer deposition (ALD), plasma-enhanced chemical vapor deposition (PECVD), electrochemical deposition, or combinations thereof. Other suitable deposition processes are within the contemplated scope of disclosure. In some embodiments, the TSV opening may be formed through the entire thickness of the substrate 8 and the conductive material may be deposited in the opening to form the TSV 109 extending between the front side 102 and the back side 103 of the substrate 8. Alternatively, the TSV opening may be formed partially through the thickness of the substrate 8 (e.g., as a blind opening) and the conductive material may be deposited in the opening. The back side 103 of the substrate 8 may then be thinned using one or more suitable processes, such as polishing, grinding, and/or etching processes, to remove portions of the substrate 8 and expose the conductive material on the back side 103 of the substrate 8. As shown in FIGS. 3B and 3C, in some embodiments the lower surface of the TSV 109 may project below the plane of the back side 104 the substrate 8. This may help facilitate making an electrical connection to the TSV 109 from the back side of the semiconductor device structure 100. In other embodiments, the TSV 109 may not extend below the plane of the back side 103 of the substrate 8.

Referring to FIG. 3B, the TSV 109 may have a vertical depth dimension D₂. In various embodiments, the vertical depth dimension D₂ of the TSV 109 may be greater than about 10 μm. In some embodiments, the vertical depth dimension D₂ of the TSV 109 may be between about 10 μm and about 100 μm (e.g., ~50 μm), although greater and lesser vertical depth dimensions D₂ of the TSV 109 are within the contemplated scope of disclosure. Referring to FIG. 3C, the upper surface of the TSV 109 may have a width dimension W₂. In various embodiments, the width dimension W₂ of the TSV 109 may be at least about 1 μm, such as about 5 μm, along both the first horizontal direction hd1 and the second horizontal direction hd2. It will be understood that greater and lesser width dimensions W₂ for the TSV 109 are within the contemplated scope of disclosure. Although FIGS. 3A-3C illustrate a single TSV 109 in the TSV region 105, in various embodiments, multiple TSVs 109 may be formed within the TSV region 105. In some embodiments, the pitch (i.e., center-to-center spacing) between adjacent TSVs 109 in the TSV region 105 may be at least about 4 μm, such as about 20 μm, although greater and lesser pitch dimensions are within the contemplated scope of disclosure. In some embodiments, a ratio of the depth dimension D₂ to the width dimension W₂ of each TSV 109 may be between about 5:1 and about 15:1, such as about 10:1. In some embodiments, a ratio of the pitch between adjacent TSVs 109 and the width dimensions W₂ of the TSVs 109 may be between about 3:1 and about 5:1, such as about 4:1. In some embodiments, the TSVs 109 may have a pattern density of 1% to 4.2% per 10000 μm², meaning that the area occupied by the TSVs 109 over every 10000 μm² of the area of the semiconductor device structure 100 may be 1~4.2%.

As discussed above, the TSVs 109 may be formed during a back end-of-line (BEOL) operation. Semiconductor devices may be formed within the OD areas 106 of the device region 104 of the semiconductor device structure 100 via front end-of-line (FEOL) operations. Such operations may include, for example, forming doped wells via masked ion implantation processes, depositing and patterning a gate dielectric layer, a gate electrode layer, a gate cap dielectric layer, and a dielectric gate spacer layer to form a plurality of gate structures, and optionally performing additional ion implantation processes to form active regions. A plurality of field effect transistors (FETs) may be formed in the OD areas 106 of the device region 104, where each FET may include a gate structure, a semiconductor channel, a pair of active regions (one of which functions as a source region and another of which functions as a drain region), and optional metal-semiconductor alloy regions over the active regions, as described above with reference to FIG. 1. For clarity of illustration, the semiconductor devices (e.g., FETs) formed in the device region 104 are not shown in FIGS. 3A-3C.

Following the above-described FEOL operations, BEOL operations may be performed to form the TSVs 109 within the TSV region(s) 105 in addition to interconnect level structures (e.g., L1-L7) as described above with reference to FIG. 1. In some embodiments, the TSVs 109 may be formed prior to forming the interconnect level structures. Alternatively, the TSVs 109 may be formed following the formation of one or more interconnect level structures. Metal interconnect structures 40 of the interconnect level structures L0-L7 may contact the TSVs 109 to electrically couple the TSVs to semiconductor devices of the semiconductor device structure 100.

Referring again to FIGS. 3A-3C, in some embodiments, a “keep out zone” (KOZ) surrounding each TSV 109 may be defined within which no semiconductor devices may be located. FIG. 3A schematically illustrates the KOZ as a dashed line around the TSV 109. As discussed above, the presence of TSVs 109 may impart thermal stresses on the substrate 8 which may result in unwanted changes to the electrical characteristics of semiconductor devices located close to the TSV 109. Thus, the KOZ may be defined surrounding each of the TSVs 109 to minimize any negative effects on the performance of the semiconductor devices caused by the TSVs 109.

In various embodiments, the TSV region 105 may include at least one DTI structure 111 as described above. In various embodiments, at least one DTI structure 111 may be located within the KOZ surrounding each of the TSVs 109. In some embodiments, one or more DTI structures 111 may partially or completely surround each of the TSVs 109. In some embodiments, at least a portion of a DTI structure 111 may be located between each TSV 109 and semiconductor devices of the adjacent device region 104 of the semiconductor device structure 100.

In various embodiments, providing one or more DTI structures 111 within the TSV region 105 proximate to the TSVs 109 may help to reduce stress on the substrate 8 due to the presence of the TSVs 109. In various embodiments, the DTI structures 111 may have a similar effect as a retaining wall. In comparison to other isolation structures, such as the above-described STI structures 107, a DTI structure 111 may provide greater resistance to the stress generated by the TSV 109 due to its relatively deeper vertical depth within the substrate 8. The DTI structures 111 may effectively block the thermal and mechanical stress caused by TSV 109 so that the TSV 109 may have less impact on the characteristics and performance of the nearby semiconductor devices.

In some embodiments, by providing DTI structures 111 within the TSV region 105 proximate to the TSVs 109, the KOZ of each TSV 109 may be made comparatively smaller. As discussed above, KOZs of 3 μm or more are often required to maintain adequate performance of the semiconductor devices. However, it would be advantageous to provide semiconductor devices in closer proximity to the TSVs 109 to maximize the number of semiconductor devices on a die and thereby increase cost effectiveness and performance. In various embodiments, providing DTI structures 111 within the TSV region 105 proximate to the TSVs 109 may enable smaller KOZs of less than 3 μm. Referring to FIGS. 3A and 3B, in various embodiments, a minimum distance, d, between the TSV 109 and the nearest semiconductor devices of the device region 104 may be less than 3 μm, such ≤1 μm, including ≤0.5 μm, while still maintaining adequate performance of the semiconductor devices.

In some embodiments, a ratio of the vertical depth dimension D₁ of a DTI structure 111 located between a TSV 109 and semiconductor devices of a semiconductor device region 104 of the semiconductor device structure 100 and a minimum distance, d, between the TSV 109 and the semiconductor devices of the semiconductor device region 104 (i.e., D₁:d) may be at least 2:1, including at least 6:1, such as 10:1 or greater. In some embodiments, the ratio D₁:d may be between about 10:1 and about 20:1.

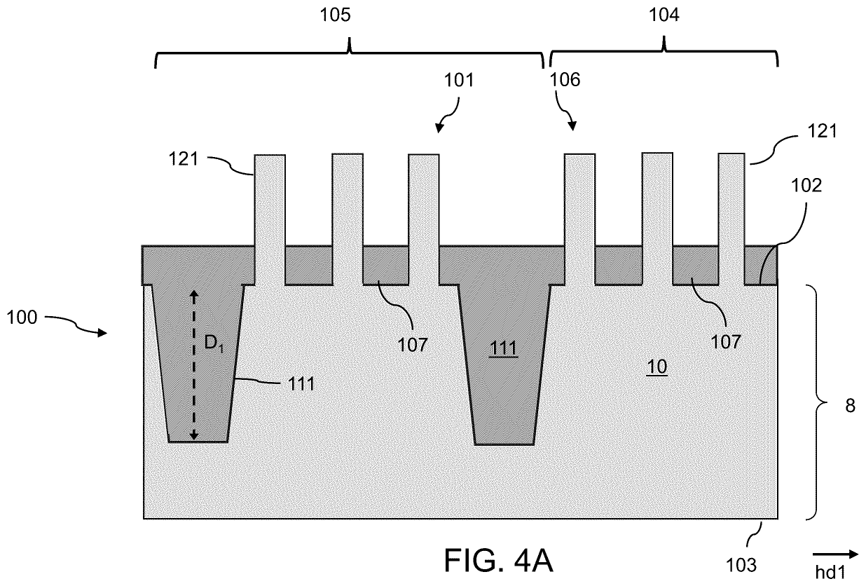

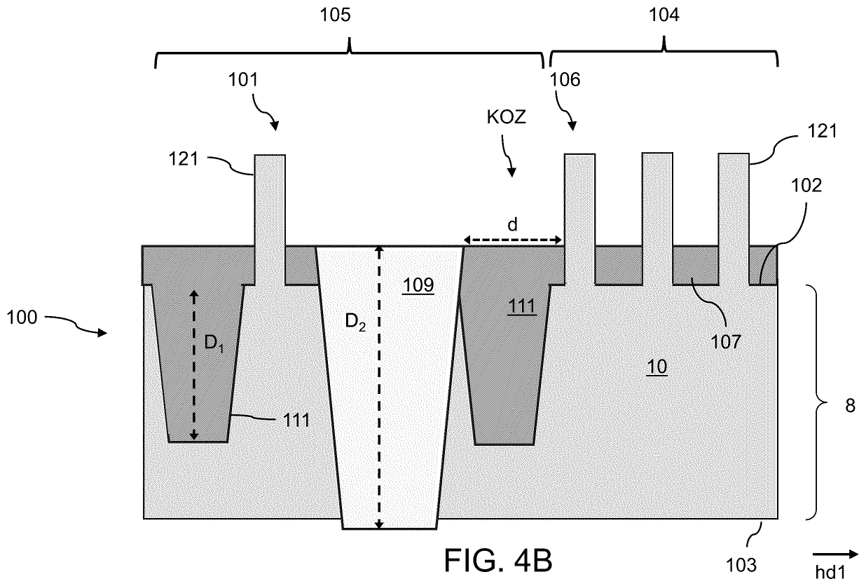

FIG. 4A is a side cross-section view of a semiconductor device structure 100 according to another embodiment of the present disclosure. The semiconductor device structure 100 of FIG. 4A may differ from the embodiment described above with reference to FIGS. 2A-3C in that the OD areas 106 of the device region 104 and the dummy OD areas 101 of the TSV region 105 may include fin structures 121. Each fin structure 121 may include a thin region of semiconductor material (e.g., silicon) that may project vertically above the upper surface 102 of the semiconductor material layer 10 of the substrate 8. Fin structures 121 within the device region 104 may be used to form semiconductor devices, such as FinFETs. FinFETs may be similar to the FET devices described above, except that the active regions (e.g., source and drain regions) and semiconductor channels of the transistors may be formed in the vertically-extending fin structures 121 rather than in a planar horizontal surface of the semiconductor material layer 10. Gate structures, which may include a gate dielectric layer, a gate electrode, and a gate cap dielectric layer, may be formed over the fin structure 121 such that the gate structure may surround the semiconductor channel on multiple (e.g., three) different sides. The fin structures 121 in the TSV region 105 may not be used to form functional semiconductor devices.

In various embodiments, the fin structures 121 shown in FIG. 4A may be formed by performing an etching process, such as an anisotropic etching process, through a photolithographically-patterned mask to remove portions of the semiconductor material layer 10 of the substrate 8 to form vertically-extending fin structures 121. An additional etching process may be used to form trenches in the semiconductor material layer 10 of the substrate in which DTI structures 111 may be subsequently formed.

A suitable dielectric material as described above may then be deposited over the fin structures 121, over the upper surface 102 of the semiconductor material layer 10 between the fin structures 121, and within each of the trenches using a suitable deposition process as described above. A planarization process, such as a CMP process, may then be performed to remove excess dielectric material from over the upper surfaces of the fin structures 121. A recess etch may then be performed to remove portions of the dielectric material from between the fin structures 121 such that the upper portions of the fin structures 121 may project above the surface of the dielectric material. The remaining dielectric material may form STI structures 107 laterally surrounding the fin structures 121 and located between adjacent fin structures 121 in the device region 104 and the TSV region 105. The remaining dielectric material also fill the trenches to form DTI structures 111 within the TSV region 105. In the embodiment of FIG. 4A, the DTI structures 111 may be continuous with the STI structures 107 that surround the fin structures 121. The DTI structures 111 may have a vertical depth dimension D₁ with respect to the front side 102 of the semiconductor material layer 10 of the substrate 8 from which the fin structures 121 vertically extend. D₁ may be greater than 3 μm, such as about 5 μm, including between about 5 μm and about 10 μm. In the embodiment of FIG. 4A, the DTI structures 111 may be discrete DTI structures 111 rather than a continuous grid of DTI structures 111 as shown in FIG. 2A.

FIG. 4B is a side cross section view of a semiconductor device structure 100 including a TSV 109 formed within a TSV region 105 of the semiconductor device structure 100 according to an embodiment of the present disclosure. Referring to FIG. 4C, one or more TSVs 109 may be formed in the TSV region 105 of the semiconductor device structure 100 shown in FIG. 4A. The one or more TSVs 109 may be similar or identical to the TSV 109 described above with reference to FIGS. 3A-3C. Thus repeated discussion of like elements is omitted for brevity. The TSVs 109 may be formed by forming one or more TSV openings within the TSV region 105 as described above. The TSV opening(s) may be formed by performing an etching process through fin structures 121, STI structures 107 and/or DTI structures 111 of the TSV region 105 and into the substrate 8. A conductive material may be deposited within the TSV opening(s) as described above to form the TSV(s) 109.

Semiconductor devices, such as above-described FinFETS (not expressly shown in FIG. 4B), may be formed in the device region 104 of the semiconductor device structure 100. One or more of the DTI structures 111 may be located within the KOZ of each TSV 109, and at least a portion of a DTI structure 111 may be located between each TSV 109 and the nearest semiconductor device of the adjacent device region 104. As discussed above, the DTI structure(s) 111 may reduce stress in the substrate 8 such that the effect of the TSV 109 on the characteristics and performance of the semiconductor devices may be minimized.

In various embodiments the minimum distance, d, between the TSV 109 and the nearest semiconductor devices of the device region 104 may be less than 3 μm, such ≤1 μm, including ≤0.5 μm. In some embodiments, the ratio of the vertical depth dimension D₁ of a DTI structure 111 located between a TSV 109 and semiconductor devices of a semiconductor device region 104 of the semiconductor device structure 100 and the minimum distance, d, between the TSV 109 and the semiconductor devices of the semiconductor device region 104 (i.e., D₁:d) may be greater than 1, such as at least 2:1, including at least 6:1. In some embodiments, the ratio D₁:d may be at least about 10:1, such as between about 10:1 and about 20:1.

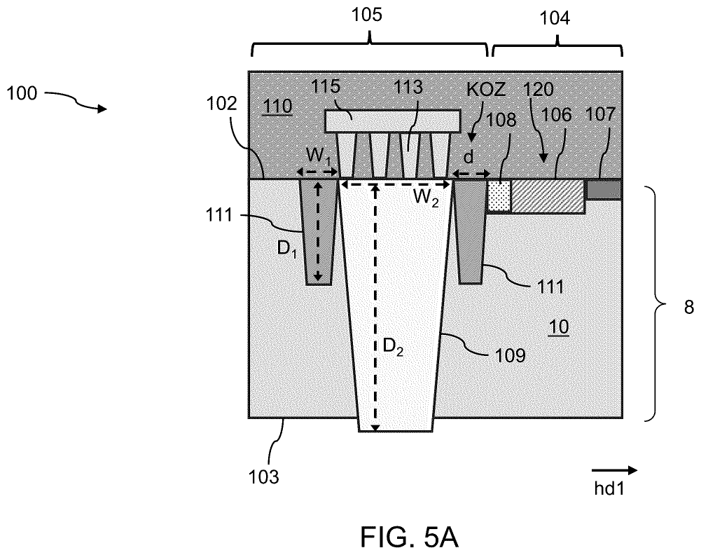

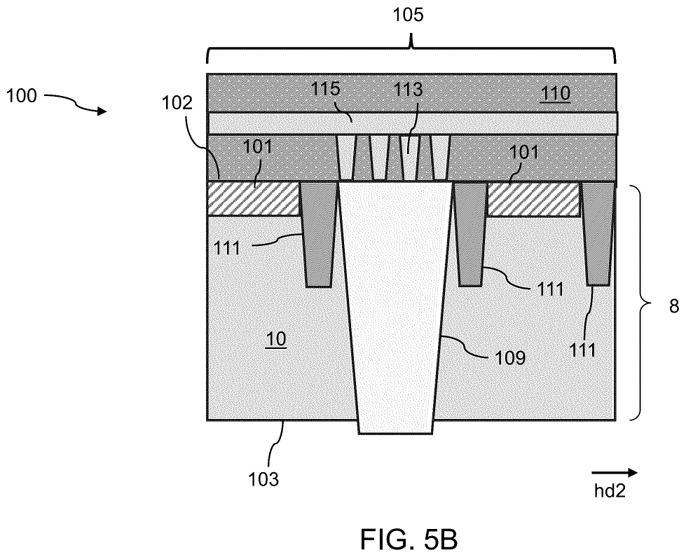

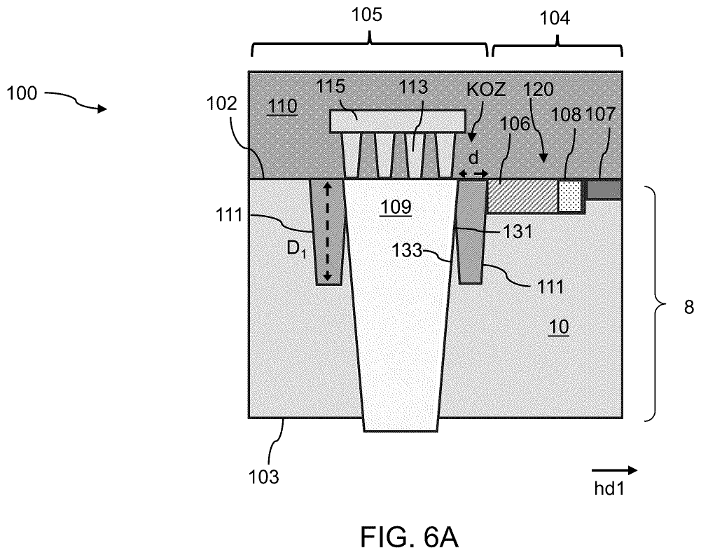

FIG. 5A is a vertical cross-section view of a semiconductor device structure 100 according to another embodiment of the present disclosure. FIG. 5A illustrates a TSV 109 within the TSV region 105 of the semiconductor device structure 100. A pair of DTI structures 111 are located on opposite sides of the TSV 109. In various embodiments, the DTI structures 111 may include discrete DTI structures 111, or may include a continuous DTI structure 111 that may partially or fully surround the TSV structure 111. At least a portion of a DTI structure 111 may be located between the TSV structure 111 and the device region 104 of the semiconductor device structure 100. FIG. 5A illustrates the DTI structures 111 located adjacent to the TSV structure 111, however it will be understood that the DTI structures 111 may be spaced away from the TSV structure 111 in various embodiments. The structures and dimensions of the TSV structure 111 and the DTI structures 111 may be similar to those discussed above with reference to FIGS. 2A-2C. Thus, repeated discussion of like features is omitted for brevity.

FIG. 5A also illustrates a semiconductor device (schematically illustrated by arrow 120) located within the device region 104 of the semiconductor device structure 100. The semiconductor device 120 may be formed in an above-described OD area 106. The OD area 106 may be adjacent to the TSV region 105 and may located between a DTI structure 111 of the TSV region 105 and an isolation feature (e.g., an STI structure 107) of the device region 104. The semiconductor device 120 may include at least one implant region 108 (e.g., an N+/p+region) that may function as an active region (e.g., source or drain region) of the semiconductor device 120. A minimum distance, d, between the TSV 109 and the semiconductor device 120 may be less than 3 μm, such ≤1 μm, including ≤0.5 μm. In some embodiments, the ratio D₁:d may be greater than 1, such as at least 2:1, including at least 6:1. In some embodiments, the ratio D₁:d may at least 10:1, such as between about 10:1 and about 20:1.

FIG. 5A also illustrates a dielectric material 110 over the substrate 8, the TSV 109 and DTI structures 111 in the TSV region 105, and the semiconductor device 120 and the STI structure 107 in the device region 104. Metal interconnect structures, including a metal line 115 and metal vias 113 may be located within the dielectric material 110. The metal vias 113 may contact the upper surface of the TSV 109 and may electrically couple the TSV 109 to the metal line 115. In various embodiments, the dielectric material 110 may include a planarization dielectric layer and/or an interconnect level dielectric (ILD) layer as described above with reference to FIG. 1. The metal line 115 and metal vias 113 may include metal interconnect structures 40 as described above with reference to FIG. 1.

FIG. 5B is a vertical cross-section view of the semiconductor device structure 100 of FIG. 5A viewed along a transverse direction according to an embodiment of the present disclosure. That is, the semiconductor device structure 100 is viewed along a first horizontal direction hd1 in FIG. 5A and is viewed along a second horizontal direction hd2 that is perpendicular to the first horizontal direction hd1 in FIG. 5B. FIG. 5B illustrates the TSV region 105 of the semiconductor device structure 100. Referring to FIG. 5B, a pair of DTI structures 111 are illustrated on opposite sides of the TSV 109. The DTI structures 111 may include discrete DTI structures 111, or may include a continuous DTI structure 111 that may partially or fully surround the TSV structure 111. The TSV region 105 further includes dummy OD regions 101. In some embodiments, at least some of the dummy OD regions 101 may be located between respective pairs of DTI structures 111. FIG. 5B also illustrates the dielectric material 110 having a metal line 115 and metal vias 113 located therein. In this embodiment, the metal line 115 may extend along the second horizontal direction hd2. In other embodiments, the metal line 115 may extend along the first horizontal direction hd1.

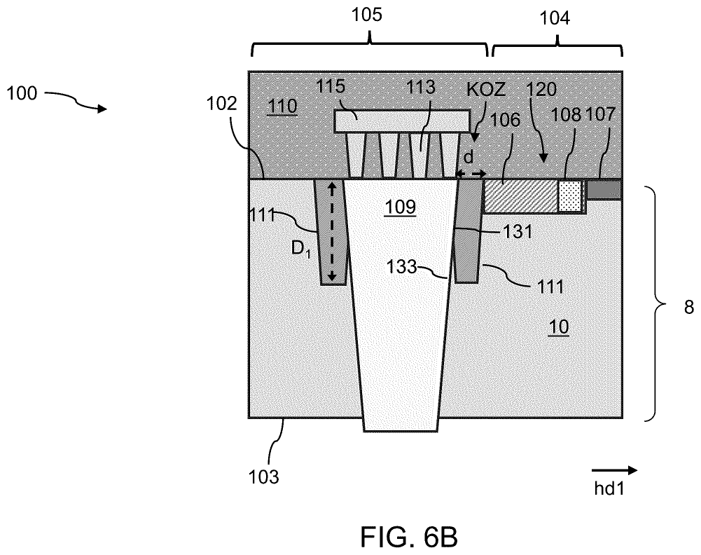

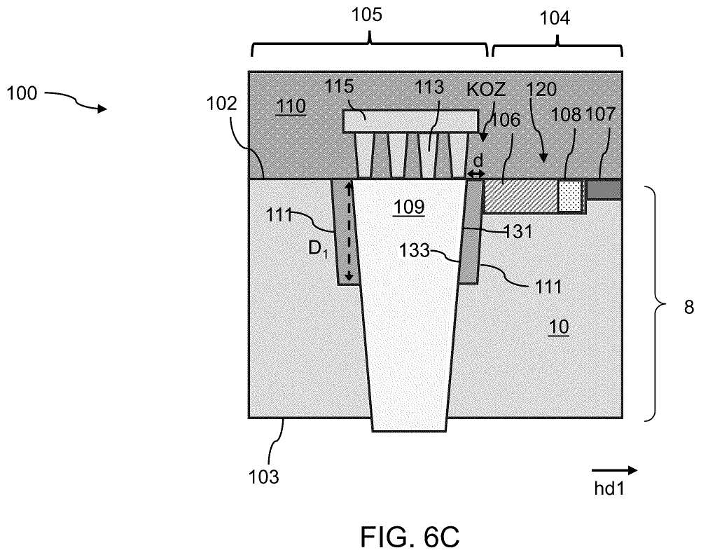

FIG. 6A is a vertical cross-section view of a semiconductor device structure 100 according to another embodiment of the present disclosure. The semiconductor device structure 100 of FIG. 6A is similar to the semiconductor device structure 100 shown in FIG. 5A. This, repeated discussion of like features is omitted for brevity. In the embodiment of FIG. 6A, the TSV 109 is formed through a portion of the DTI structures 111 located on either side of the TSV 109. Thus, the side surfaces 131 of each of the DTI structures 111 may contact the side surface 133 of the TSV 109 over at least a portion of the length of the DTI structures 111 along their depth dimension D₁. In the embodiment of FIG. 6A, the TSV 109 contacts the side surfaces 133 of the DTI structures 111 along less than half of the length of DTI structures 111.

FIG. 6B is a vertical cross-section view of a semiconductor device structure 100 according to another embodiment of the present disclosure. The semiconductor device structure 100 of FIG. 6B is similar to the semiconductor device structure 100 shown in FIG. 6A, except that in the embodiment of FIG. 6B, the TSV 109 contacts the side surfaces 133 of the DTI structures 111 along more than half of the length of DTI structures 111.

FIG. 6C is a vertical cross-section view of a semiconductor device structure 100 according to another embodiment of the present disclosure. In the embodiment of FIG. 6C, the TSV 109 contacts the side surfaces 133 of the DTI structures 111 along the entire length of DTI structures 111.

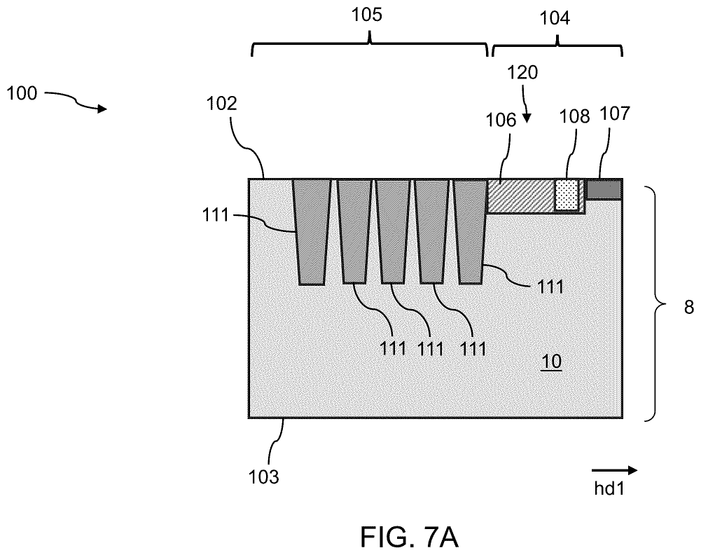

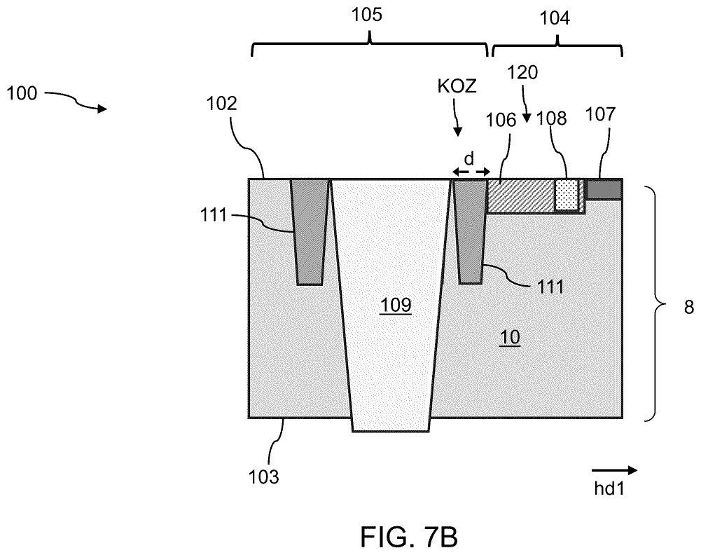

FIGS. 7A-9B illustrate various configurations for the layout of DTI structures 111 and the formation of TSVs 111 within the TSV region 105 of a semiconductor device structure 100 according to various embodiments of the present disclosure. FIG. 7A is a vertical cross-section view of a semiconductor device structure 100 including a plurality of DTI structures 111 arranged along a line. FIG. 7B is a vertical cross-section view of the semiconductor device structure 100 of FIG. 7A including a TSV 109 formed through several of the DTI structures 111 and surrounded on opposite sides by the remaining DTI structures 111.

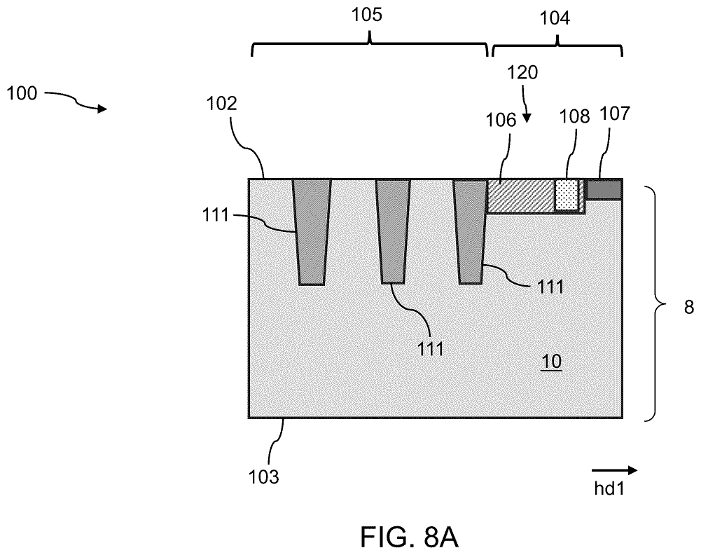

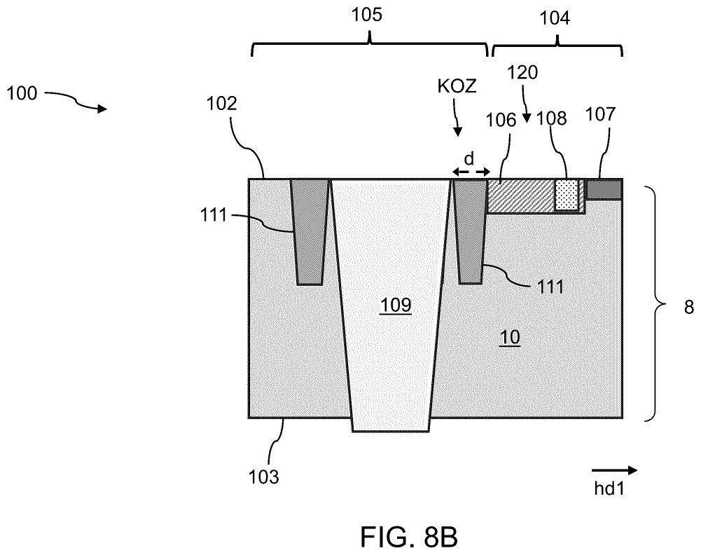

FIG. 8A is a vertical cross-section view a semiconductor device structure 100 including three DTI structures 111 that are spaced apart from one another arranged along a line. FIG. 8B is a vertical cross-section view of the semiconductor device structure 100 of FIG. 8A including a TSV 109 formed through the middle DTI structure 111 and surrounded on opposite sides by the remaining two DTI structures 111.

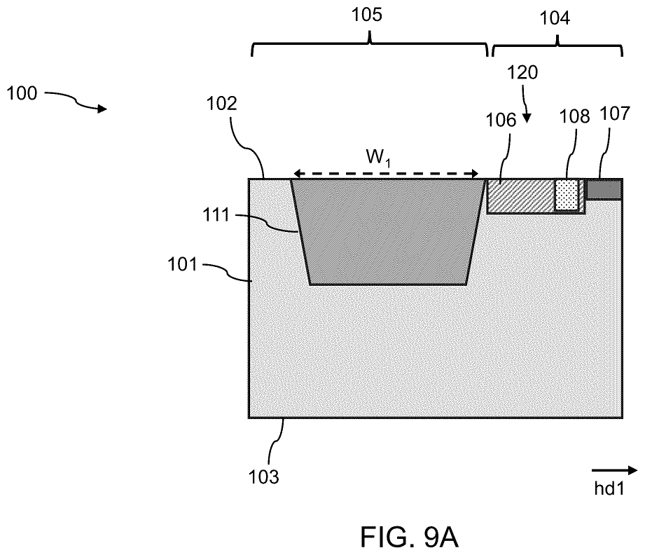

FIG. 9A is a vertical cross-section view of a semiconductor device structure 100 including a single DTI structure having a relatively larger width dimension W₁ (i.e., larger than the width dimension W₂ of the TSV 109 to be subsequently formed) along at least the first horizontal direction hd1. FIG. 9B is a vertical cross-section view of the semiconductor device structure 100 of FIG. 9A including a TSV 109 formed through the DTI structure 111 such that the DTI structure 111 contacts the TSV 109 on opposite sides of the TSV 109. In some embodiments, the DTI structure 111 may surround the entire outer perimeter of the TSV 109.

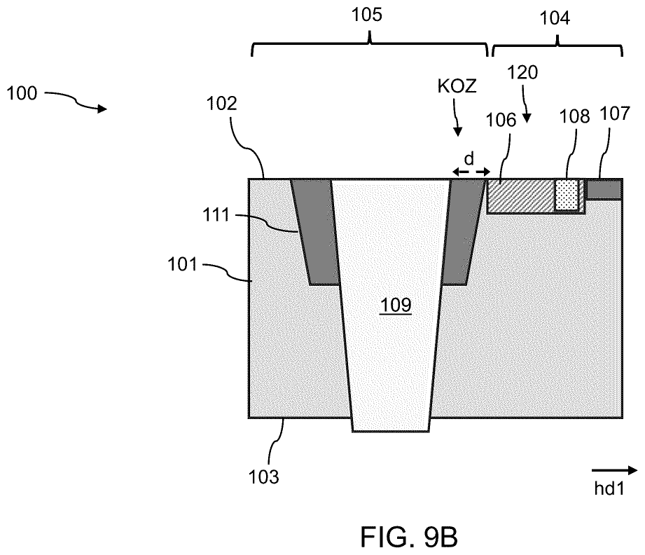

FIG. 10 is a vertical cross-section view of a semiconductor device structure 100 according to another embodiment of the present disclosure. The semiconductor device structure of FIG. 10 may be derived from the semiconductor device structure 100 described above with reference to FIG. 5A. Thus, repeated discussion of like features is omitted for brevity. The semiconductor device structure of FIG. 10 further includes contact structures 139 on the OD area 106 and implant region 108 in the device region 104, metal lines 143, and metal vias 141 extending between the metal lines 143 and the contact structures 139. The metal lines 143 and metal vias 141 may include metal interconnect structures 40 as described above with reference to FIG. 1.

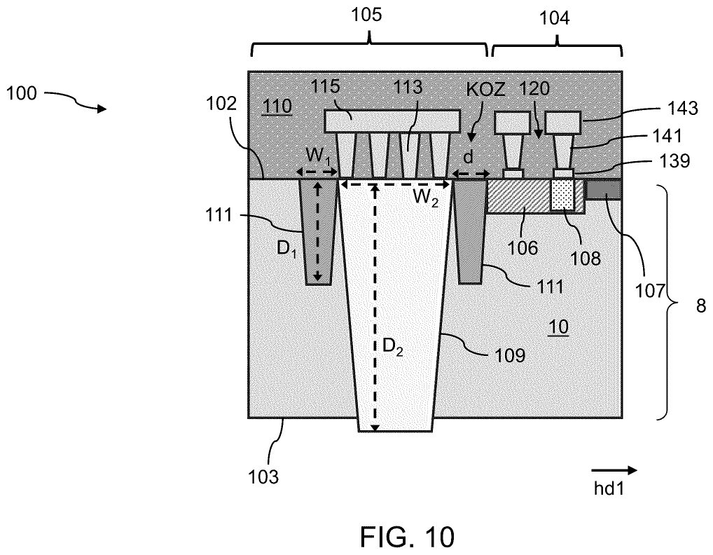

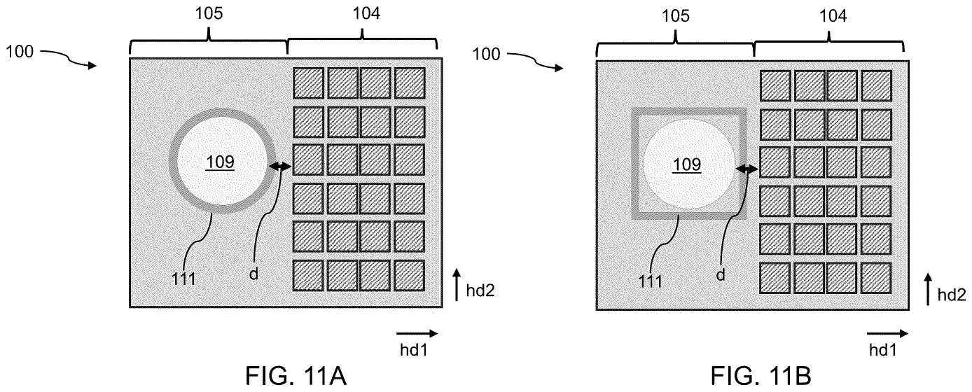

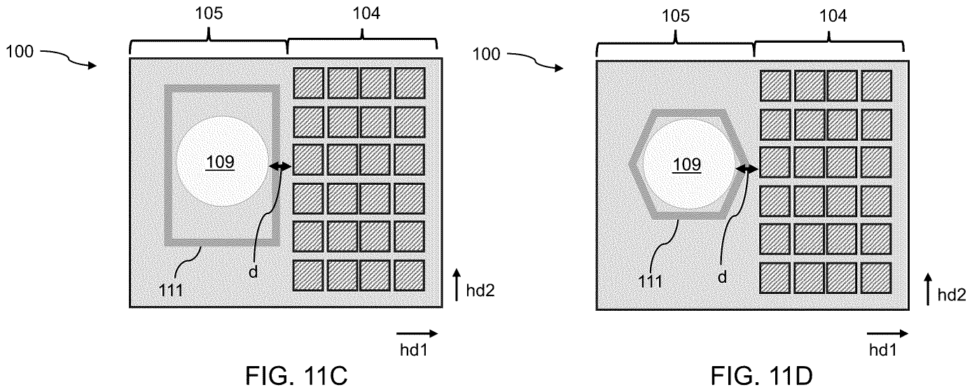

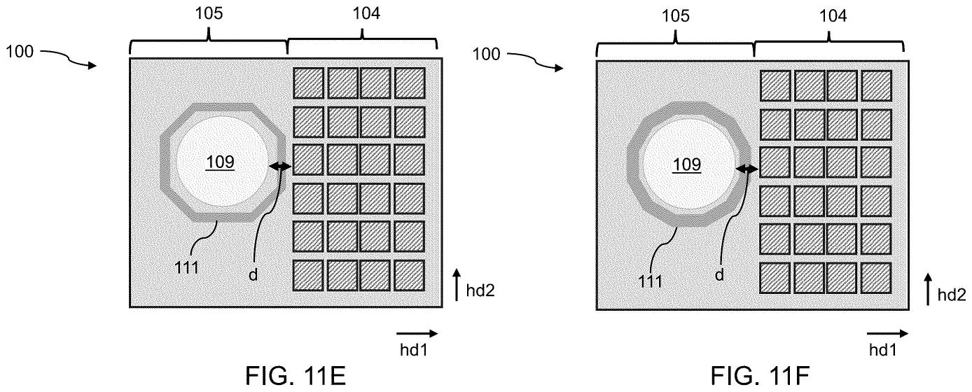

FIGS. 11A-11F are horizontal cross-section views illustrating the layout of a semiconductor device structure 100 according to various embodiments of the present disclosure. FIG. 11A is horizontal cross-section view of a semiconductor device structure 100 illustrating a device region 104 and a TSV region 105 including a TSV 109 and a circular shaped DTI structure 111 surrounding the TSV 109 according to an embodiment of the present disclosure. The TSV 109 may be separated from the device region 104 by a distance, d, as described above. Although FIG. 11A illustrates a single DTI structure 111 surrounding the entire outer periphery of the TSV 109, it will be understood that a plurality of discrete DTI structures 111 may be arranged around the TSV 109 in a circular pattern as shown in FIG. 11A. In the embodiment of FIG. 11A, the DTI structure(s) 111 shown immediately adjacent to the TSV 109, although it will be understood that a gap may be present between the TSV 109 and the surrounding DTI structure(s) 111. In addition, although the embodiment of FIG. 11A illustrates a gap between the DTI structure(s) 111 and the device region 104, in other embodiments, the DTI structure(s) 111 may abut the device region 104.

FIG. 11B is horizontal cross-section view of a semiconductor device structure 100 illustrating a device region 104 and a TSV region 105 including a TSV 109 and a square shaped DTI structure 111 surrounding the TSV 109 according to another embodiment of the present disclosure. The DTI structure 111 may be a continuous structure extending around the periphery of the TSV 109 or may include a plurality of discrete DTI structures 111 forming a square pattern as shown in FIG. 11B. In the embodiment of FIG. 11B, there is a gap between the TSV 109 and the DTI structure(s) 111 surrounding the TSV 109, although in other embodiments, the DTI structure(s) 111 may contact the TSV 109.

FIG. 11C is horizontal cross-section view of a semiconductor device structure 100 illustrating a device region 104 and a TSV region 105 including a TSV 109 and a rectangular shaped DTI structure 111 surrounding the TSV 109 according to another embodiment of the present disclosure. The DTI structure 111 may be a continuous structure extending around the periphery of the TSV 109 or may include a plurality of discrete DTI structures 111 forming a rectangular pattern as shown in FIG. 11C. In the embodiment of FIG. 11C, there is a gap between the TSV 109 and the DTI structure(s) 111 surrounding the TSV 109, although in other embodiments, the DTI structure(s) 111 may contact the TSV 109.

FIG. 11D is horizontal cross-section view of a semiconductor device structure 100 illustrating a device region 104 and a TSV region 105 including a TSV 109 and a hexagonal shaped DTI structure 111 surrounding the TSV 109 according to another embodiment of the present disclosure. The DTI structure 111 may be a continuous structure extending around the periphery of the TSV 109 or may include a plurality of discrete DTI structures 111 forming a hexagonal pattern as shown in FIG. 11D. In the embodiment of FIG. 11D, there is a gap between the TSV 109 and the DTI structure(s) 111 surrounding the TSV 109, although in other embodiments, the DTI structure(s) 111 may contact the TSV 109.

FIG. 11E is horizontal cross-section view of a semiconductor device structure 100 illustrating a device region 104 and a TSV region 105 including a TSV 109 and an octagonal shaped DTI structure 111 surrounding the TSV 109 according to another embodiment of the present disclosure. The DTI structure 111 may be a continuous structure extending around the periphery of the TSV 109 or may include a plurality of discrete DTI structures 111 forming an octagonal pattern as shown in FIG. 11E. In the embodiment of FIG. 11E, there is a gap between the TSV 109 and the DTI structure(s) 111 surrounding the TSV 109, although in other embodiments, the DTI structure(s) 111 may contact the TSV 109.

FIG. 11F is horizontal cross-section view of a semiconductor device structure 100 illustrating a device region 104 and a TSV region 105 including a TSV 109 and a polygonal shaped DTI structure 111 surrounding the TSV 109 according to another embodiment of the present disclosure. The polygonal shaped DTI structure 111 may have an arbitrary number of sides, which may be of equal or unequal lengths. The DTI structure 111 may be a continuous structure extending around the periphery of the TSV 109 or may include a plurality of discrete DTI structures 111 forming a polygonal pattern as shown in FIG. 11F. In the embodiment of FIG. 11F, there is a gap between the TSV 109 and the DTI structure(s) 111 surrounding the TSV 109, although in other embodiments, the DTI structure(s) 111 may contact the TSV 109.

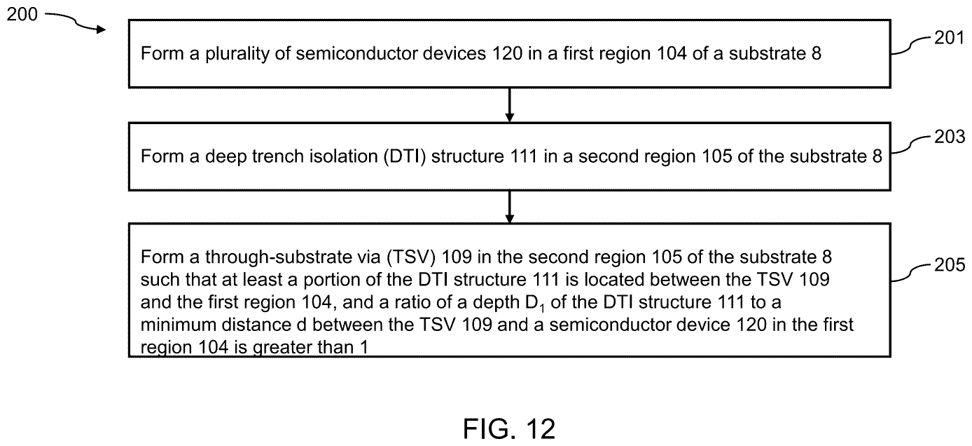

FIG. 12 is a flow diagram illustrating steps of a method 200 of forming a semiconductor device structure 100 according to various embodiments of the present disclosure. Referring to FIGS. 2A, 2B, 3A, 3B, 4A-5A and 6A-12, in step 201 of method 200, a plurality of semiconductor devices 120 may be formed in a first region 104 of a substrate 8. Referring to FIGS. 2A-12, in step 203 of method 200, a deep trench isolation (DTI) structure 111 may be formed in a second region 105 of the substrate 8. Referring to FIGS. 3A-3C, 4B-6C, 7B, 8B and 9B-12, in step 205 of method 200, a through-substrate via (TSV) 109 may be formed in the second region 105 of the substrate 8 such that at least a portion of the DTI structure 111 is located between the TSV 109 and the first region 104, and a ratio of a depth D₁ of the DTI structure 111 to a minimum distance d between the TSV 109 and a semiconductor device 120 in the first region 104 is greater than 1.

Referring to all drawings and according to various embodiments of the present disclosure, a semiconductor device structure 100 may include a device region 104 including a plurality of semiconductor devices 120, and a through-substrate via (TSV) region 105 including a TSV 109 extending through a substrate 8, and a deep trench isolation (DTI) structure 111 within the substrate 8, where at least a portion of the DTI structure 111 is located between the TSV 109 and the device region 104, and a ratio of a depth D1 of the DTI structure 111 to a minimum distance d between the TSV 109 and a semiconductor device 120 in the device region 104 is greater than 1.

In an embodiment, the ratio of the depth D1 of the DTI structure 111 to the minimum distance d between the TSV 109 and the semiconductor device 120 in the device region 104 is ≥6:1. In another embodiment, the ratio of the depth D1 of the DTI structure 111 to the minimum distance d between the TSV 109 and the semiconductor device 120 in the device region 104 is ≥10:1. In another embodiment, the depth D1 of the DTI structure 111 is greater than 3 μm. In another embodiment, depth D1 of the DTI structure 111 is ≥5 μm and ≤10 μm. In another embodiment, the minimum distance d between the TSV 109 and the semiconductor device 120 in the device region 105 is ≤0.5 μm. In another embodiment, a side surface 131 of the DTI structure 111 contacts a side surface 133 of the TSV 109. In another embodiment, the side surface 131 of the DTI structure 111 contacts the side surface 133 of the TSV 109 along at least half of a vertical length of the DTI structure 111. In another embodiment, the side surface 131 of the DTI structure 111 contacts the side surface 133 of the TSV 109 over the entire vertical length of the DTI structure 111. In another embodiment, the TSV 109 extends through the DTI structure 111 such that the DTI structure 111 contacts the TSV 109 on opposite sides of the TSV 109.

An additional embodiment is drawn to a semiconductor device structure including a substrate 8 having a semiconductor material layer 10 forming a first surface 102 of the substrate 8, a plurality of semiconductor devices 120 located on and/or in the semiconductor material layer 10 of the substrate 8 in a first region 104, at least one deep trench isolation (DTI) structure 111 in a second region 105, the at least one DTI structure 111 including a dielectric material extending into the substrate 8 to a depth D1 of greater than 3 μm from the first surface 102 of the substrate 8, and a through-substrate via (TSV) 109 including a conductive material extending between the first surface 102 of the substrate 8 and a second surface 104 of the substrate 8 opposite the first surface 102, where the TSV 109 is located in the second region 105 and at least a portion of a DTI structure 111 is located between the TSV 109 and the first region 104.

In an embodiment, the at least one DTI structure 111 extends into the substrate 8 to a depth D1 of ≥5 μm from the first surface 102 of the substrate 8, and a minimum distance d between the TSV 111 and the first region 104 is ≤0.5 μm. In another embodiment, the first region 104 includes a plurality of oxide definition (OD) areas 106 separated by first isolation features 107, and the semiconductor devices 120 include field-effect transistors (FETs) formed in the OD areas 106, and the second region 105 includes a plurality of dummy OD areas 101 separated by second isolation features including the at least one DTI structure 111. In another embodiment, the at least one DTI structure 111 includes a grid of DTI structures 111 surrounding each of the dummy OD areas 101, and the TSV 109 formed within the grid. In another embodiment, the semiconductor devices 120 include FinFETs, the plurality of dummy OD areas 101 include fin structures 121 surrounded by shallow trench isolation (STI) structures 107 including a dielectric material, and the at least one DTI structure 111 is continuous with the STI structures 107. In another embodiment, the at least one DTI structure 111 forms at least one of a circular, square, rectangular, hexagonal, octagonal, or polygonal pattern surrounding the TSV 109.

An additional embodiment is drawn to a method of fabricating a semiconductor device structure that includes forming a plurality of semiconductor devices 120 in a first region 104 of a substrate 8, forming a deep trench isolation (DTI) structure 111 in a second region 105 of the substrate 8, forming a through-substrate via (TSV) 109 in the second region 105 of the substrate 8 such that at least a portion of the DTI structure 111 is located between the TSV 109 and the first region 104, and a ratio of a depth D1 of the DTI structure 111 to a minimum distance d between the TSV 109 and a semiconductor device 120 in the first region 104 is greater than 1.

In an embodiment, forming the DTI structure 111 includes performing a first etching process through a first mask to remove a portion of the substrate 8 to form a first opening, depositing a dielectric material within the first opening to form the DTI structure 111 laterally surrounded by the substrate 8, and where forming the TSV 109 includes performing a second etching process through a first mask to remove a portion of the DTI structure 111 to form a second opening, depositing a conductive material within the second opening to form the TSV 109 contacting the DTI structure 111. In another embodiment, the DTI structure 111 contacts the TSV 109 on opposite sides of the TSV 109. In another embodiment, a plurality of DTI structures 111 are formed in the second region 105, and where forming the TSV 109 includes performing an etching process through a mask to form a TSV opening by removing a portion of the substrate 8 and at least one DTI structure 111 of the plurality of DTI structures 111, and depositing a conductive material within the TSV opening to form the TSV 109, where at least a portion of a remaining DTI structure 111 of the plurality of DTI structures 111 is located between the TSV 109 and the first region 104.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a device region comprising a plurality of semiconductor devices; and
a through-substrate via (TSV) region, comprising:
a TSV extending through a substrate; and
a deep trench isolation (DTI) structure within the substrate, wherein at least a portion of the DTI structure is located between the TSV and the device region, and a ratio of a depth of the DTI structure to a minimum distance between the TSV and a semiconductor device in the device region is greater than 1.

2. The semiconductor device structure of claim 1, wherein the ratio of the depth of the DTI structure to the minimum distance between the TSV and the semiconductor device in the device region is ≥6:1.

3. The semiconductor device structure of claim 2, wherein the ratio of the depth of the DTI structure to the minimum distance between the TSV and the semiconductor device in the device region is ≥10:1.

4. The semiconductor device structure of claim 1, wherein the depth of the DTI structure is greater than 3 μm.

5. The semiconductor device structure of claim 4, wherein the depth of the DTI structure is ≥5 μm and ≤10 μm.

6. The semiconductor device structure of claim 1, wherein the minimum distance between the TSV and the semiconductor device in the device region is ≤0.5 μm.

7. The semiconductor device structure of claim 1, wherein a side surface of the DTI structure contacts a side surface of the TSV.

8. The semiconductor device structure of claim 7, wherein the side surface of the DTI structure contacts the side surface of the TSV along at least half of a vertical length of the DTI structure.

9. The semiconductor device structure of claim 8, wherein the side surface of the DTI structure contacts the side surface of the TSV over the entire vertical length of the DTI structure.

10. The semiconductor device structure of claim 9, wherein the TSV extends through the DTI structure such that the DTI structure contacts the TSV on opposite sides of the TSV.

11. A semiconductor device structure, comprising:
a substrate comprising a semiconductor material layer forming a first surface of the substrate;
a plurality of semiconductor devices located on and/or in the semiconductor material layer of the substrate in a first region;
at least one deep trench isolation (DTI) structure in a second region, the at least one DTI structure comprising a dielectric material extending into the substrate to a depth of greater than 3 μm from the first surface of the substrate; and
a through-substrate via (TSV) comprising a conductive material extending between the first surface of the substrate and a second surface of the substrate opposite the first surface, wherein the TSV located in the second region and at least a portion of a DTI structure is located between the TSV and the first region.

12. The semiconductor device structure of claim 11, wherein the at least one DTI structure extends into the substrate to a depth of ≥5 μm from the first surface of the substrate, and a minimum distance between the TSV and the first region is ≤0.5 μm.

13. The semiconductor device structure of claim 11, wherein:
the first region comprises a plurality of oxide definition (OD) areas separated by first isolation features, and the semiconductor devices comprise field-effect transistors (FETs) formed in the OD areas; and
the second region comprises a plurality of dummy OD areas separated by second isolation features comprising the at least one DTI structure.

14. The semiconductor device structure of claim 13, wherein the at least one DTI structure comprises a grid of DTI structures surrounding each of the dummy OD areas, and the TSV is formed within the grid.

15. The semiconductor structure of claim 13, wherein the semiconductor devices comprise FinFETs, the plurality of dummy OD areas comprise fin structures surrounded by shallow trench isolation (STI) structures comprising a dielectric material, and the at least one DTI structure is continuous with the STI structures.

16. The semiconductor structure of claim 11, wherein the at least one DTI structure forms at least one of a circular, square, rectangular, hexagonal, octagonal, or polygonal pattern surrounding the TSV.

17. A method of fabricating a semiconductor device structure, comprising:
forming a plurality of semiconductor devices in a first region of a substrate;
forming a deep trench isolation (DTI) structure in a second region of the substrate; and
forming a through-substrate via (TSV) in the second region of the substrate such that at least a portion of the DTI structure is located between the TSV and the first region, and a ratio of a depth of the DTI structure to a minimum distance between the TSV and a semiconductor device in the first region is greater than 1.

18. The method of claim 17, wherein forming the DTI structure comprises:
performing a first etching process through a first mask to remove a portion of the substrate to form a first opening; and
depositing a dielectric material within the first opening to form the DTI structure laterally surrounded by the substrate, and wherein forming the TSV comprises:
performing a second etching process through a first mask to remove a portion of the DTI structure to form a second opening; and
depositing a conductive material within the second opening to form the TSV contacting the DTI structure.

19. The method of claim 18, wherein the DTI structure contacts the TSV on opposite sides of the TSV.

20. The method of claim 17, wherein a plurality of DTI structures are formed in the second region, and wherein forming the TSV comprises:
performing an etching process through a mask to form a TSV opening by removing a portion of the substrate and at least one DTI structure of the plurality of DTI structures; and
depositing a conductive material within the TSV opening to form the TSV, wherein at least a portion of a remaining DTI structure of the plurality of DTI structures is located between the TSV and the first region.
